(19) United States
(12) Patent Application Publication
(10) Pub. No.: US 2010/0283541 A1
(43) Pub. Date: Nov. 11, 2010

(54) SIGNAL LEVEL DETECTOR WITH HYSTERESIS CHARACTERISTIC

(75) Inventor: Keiji Tanaka, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: Sumitomo Electric Industries, Ltd., Osaka (JP)

(21) Appl. No.: 12/771,025

(22) Filed: Apr. 30, 2010

(30) Foreign Application Priority Data
May 7, 2009 (JP) 2009-112903

(51) Int. Cl. H03F 3/45

(52) U.S. Cl. 330/252

(57) ABSTRACT

A signal level detector is disclosed, in which the noise tolerance of the signal detection is enhanced without increasing power consumption of the circuit. The signal detector includes two amplifiers, whose gain is fixed but different from each other, a switch to select the output of one of the amplifiers, a peak hold to hold the selected output and a comparator to compare the output of the peak hold with the level corresponding to loss-of-signal level. The switch responds to the compared result. In the invention, the two amplifiers have the same arrangement of the trans-conductance amplifier but only the resistance of the emitter coupling resistor is different.

### BACKGROUND OF THE INVENTION

1. Field of the Invention

The present invention relates to a level detector for an input signal, in particular, the invention relates to a level detector usable in an optical receiver circuit.

2. Related Background Art

Conventional signal detector and a system to process the detected signal are comprised of a variable gain amplifier, another variable gain amplifier to provide a reference, two peak hold each configured in the downstream of respective variable gain amplifiers, and a hysteresis comparator to compare outputs of these two outputs of the peak holds. A Japanese Patent Application published as H08-015584A has disclosed such signal detector. The Signal detector disclosed therein adjusts the gain of variable gain amplifiers by following the level corresponding to the loss of signal (hereafter denoted as LOS). Because the comparator shows the hysteresis, the noise tolerance of the level detector may be secured.

However, the conventional level detector needs a wide linearity or the variable gain amplifier even at a level close to reset the LOS status for the variable gain amplifier is usually necessary to be wide linearity. In order to enhance the noise tolerance, the wide dynamic range in the linearity is necessary, which makes hard to accomplish by the variable gain amplifier without increasing the power consumption of the amplifier. The present invention is to provide a technique to enhance the noise tolerance in the signal level detector without increasing the power consumption.

### SUMMARY OF THE INVENTION

The signal level detector according to the present invention includes two amplifiers each receiving an input signal, a switch to select one of outputs of the first and second amplifiers, a peak hold to hold an output of the switch, that is, one of the outputs of two amplifiers selected by the switch, and a comparator that compares the output of the peak hold with a reference corresponding to the LOS threshold. The signal level detector of the invention has a feature that two amplifiers that receive the input signal have the same circuit arrangement but different voltage gain and the switch selects one of the outputs of the amplifiers by responding to the output of the comparator.

The level detector of the invention switches the amplifiers with different gain to each other by responding to the output of the comparator that corresponds to the LOS status, which may show the hysteresis performance for the LOS status. Because the switch makes only one of the amplifiers active and the other amplifier inactive, the power consumption of the detector does not increase.

Two amplifiers of the present detector each has a feature that the circuit arrangement thereof is a type of a trans-conductance amplifier with a pair of differential transistors, a pair of source transistors each connected to one of differential transistors, and a emitter coupling resistor connected between the emitters of the differential transistors, or connected between the collectors of the source transistors. In the present level detector, only the resistance of the emitter coupling resistor is different from the resistance of the emitter coupling resistor of the other amplifier. The LOS alarm output from the comparator controls the active or the inactive status of two trans-conductance amplifiers by turning on or turning off the source transistors. Because one of the amplifier not selected by the LOS alarm signal becomes inactive, the power consumption of the level detector does not increase even through the level detector includes two amplifiers.

Two trans-conductance amplifiers have common load resistors, that is, the differential transistors of two amplifiers are connected in parallel with respect to their load resistors. Accordingly, the output amplitude of two trans-conductance amplifiers become equal to a value determined by the resistance of the load resistor multiplied by a current determined by the source transistors. Because the size of the source transistors of two trans-conductance amplifiers is same to each other, the magnitude of the output signal of the trans-conductance amplifiers becomes equal but the voltage gain thereof is different because the emitter coupling resistor has resistance different in respective trans-conductance amplifiers.

### BRIEF DESCRIPTION OF DRAWINGS

The foregoing and other purposes, aspects and advantages will be better understood from the following detailed description of a preferred embodiment of the invention with reference to the drawings, in which:

FIG. 1 is a block diagram of a signal level detector according to an embodiment of the present invention;

FIG. 2 is a circuit diagram of a hysteresis controller implemented in the signal level detector of the present invention; and

FIGS. 3A to 3C show examples of the operation of the signal detector, where FIG. 3A is a behavior of an input signal, FIG. 3B is an alarm status responding to the input signal shown in FIG. 3A, and FIG. 3C explains a mechanism of the hysteresis control.

### DETAILED DESCRIPTION OF PREFERRED EMBODIMENTS

Next, preferred embodiment according to the present invention will be described as referring to accompanying drawings. In the description of the drawings, the same numerals or the symbols will refer to the same elements without overlapping explanations.

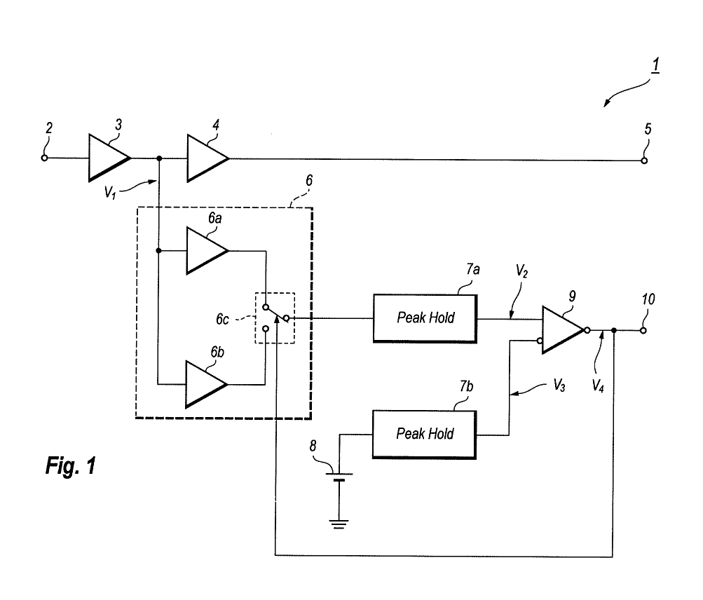

FIG. 1 is a circuit diagram of a level detector 1 according to an embodiment of the present invention. The level detector 1 decides whether the optical input level is under the LOS status or not by using the hysteresis characteristic, and comprises a signal input terminal 2, two amplifiers, 3 and 4, a signal output terminal 5, a hysteresis controller 6, two peak holds, 7a and 7b, a reference 8, a comparator 9 and an alarm terminal 10. The first amplifier 3 receives a signal from, for instance a trans-impedance amplifier ordinary provided in an optical receiver, and outputs an amplified signal V1 to the second amplifier 4 and the hysteresis controller 6. The second amplifier 4 may operate as a limiting amplifier whose output saturates at a preset level able to be processed in, for instance a clock data recovery unit ordinarily provided in the downstream of the output terminal 5.

The hysteresis controller 6 includes two amplifiers, 6a and 6b, configured in parallel with respect to the input thereof and a switch 6c. Respective outputs of the amplifiers, 6a and 6b, are brought to the terminals of the switch 6c. The switch 6c may select one of the outputs of the amplifiers, 6a and 6b, and transmit the selected output to one of the peak hold 7a.

The peak hold 7a detects a peak level of one of the outputs selected by the switch 6c, and generates a first detected signal V2 to the comparator 9. The other peak hold 7b has substantially same configuration with that of the first peak hold 7a. The second peak hold 7b detects a peak level of the reference 8 and transmits the peak level V3 thus detected to the comparator 9.

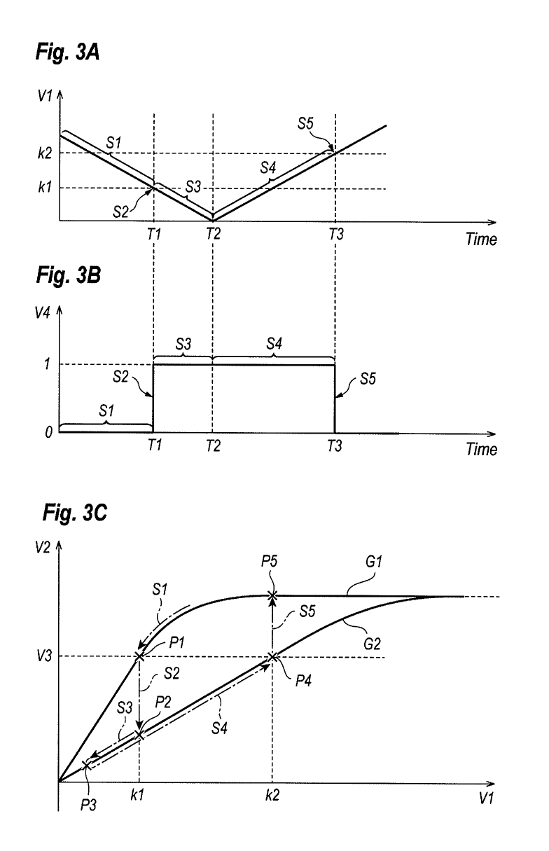

The comparator 9 compares the first peak level V2 output from the first peak hold 7a with the second peak level V3 output from the second peak hold 7b, and generates an alarm V4 that corresponds to the decision for the input level of the level detector 1 and has only two logical levels of “1” and “0”, refer to FIG. 3B. Specifically, when the signal V1 is less than a preset level corresponding to the reference 8, which means that the optical input level is in the LOS state, the alarm V4 becomes logical “1”, while, the signal V1 is greater than or equal to the preset level, the alarm V4 takes the logical level of “0”. This alarm V4 is not only output from the alarm terminal but sent to the switch 6c.

The switch 6c, when it receives the alarm V4 with the logical level of “1” from the comparator 9, which means that the optical input level changes from the SD state to the LOS state, changes the selection of the output to be transmitted to the first comparator 7a from the first amplifier 6a to the second amplifier 6b. On the other hand, when the switch 6c receives the alarm V4 with the level “0”, which means that the optical input level changes from the LOS state to the SD state, the switch changes the output of the second amplifier 6b to the first amplifier 6a.

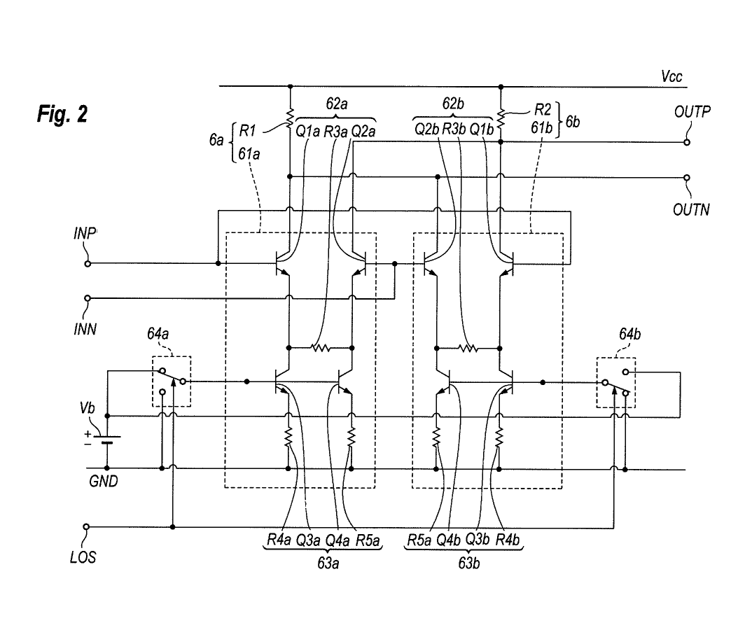

The switch 6c shown in FIG. 1 is schematically illustrated so as to show only the function to select the output of two amplifiers, 6a and 6c. The arrangement of the switch 6c is not restricted to those shown in FIG. 1; accordingly, the description presented below assumes that the function of the switch 6c makes only one of the amplifiers, 6a and 6c, active. In such an arrangement, the output of the amplifiers, 6a and 6c, may be directly connected to the input of the peak hold 7a without passing the switch 6c as shown in FIG. 2.

The gain of the first amplifier 6a is set to be greater than the gain of the second amplifier 6b. The upper limit of the input signal V1 for the amplifier, where the upper limit means the largest threshold in the range where the amplifier may linearly operate, is set to a value corresponding to the LOS asserting level k1, refer to FIGS. 3A and 3C. While, the LOS de-asserting level k2 is set to be greater than the LOS asserting level k1, and a difference between these levels is identical with an amount of the hysteresis of the level detector 1.

Next will describe a detail of the hysteresis controller 6. FIG. 2 is a circuit diagram of the hysteresis controller 6, which comprises the first amplifier section 6a, the second amplifier section 6b and the switch section, 64a and 64b. The hysteresis controller 6 further provides two input terminals, INP and INN, two output terminals, OUTP and OUTN. The input terminals, INP and INN, are each connected to the outputs of the amplifier 3 shown in FIG. 1 to receive the signal V1 from the amplifier 3. The outputs, OUTP and OUTN, are each connected to the input of the peak hold 7a. The signal V1 input from the terminals, INP and INN, is amplified by one of the amplifier units, 6a and 6c, and only one of the amplified signal is appeared in the output terminals, OUTP and OUTN.

The first amplifier section 6a includes a trans-conductance amplifier 61a that is comprised of a differential unit 62a including a pair of transistors, Q1a and Q2a, called as the differential pair and an emitter coupling resistor R3a; and a current source 63a including two transistors, Q3a and Q4a, called as the source transistors and two emitter resistors, R4a and R5a. The first transistor Q1a receives the signal V1 in the positive phase thereof from the terminal INP, while, the second transistor Q2a receives the signal V1 in the negative phase from the terminal INN. The first transistor Q1a has a load resistor R1 connected to the power supply Vcc, while the second transistor Q2a has another load resistor R2 also connected to the power supply Vcc; and the collector of respective transistors, Q1a and Q2a, are coupled with the terminals, OUTP and OUTN.

The base of the source transistors, Q3a and Q3b, each receives the reference Vb through the switch 64a; the emitter of these transistors are grounded through respective resistors, R4a and R5a; while, the collectors thereof are connected to the emitter of corresponding transistors, Q1a and Q2a. Between the collectors are connected with the emitter coupling resistor R3a. The other trans-conductance amplifier 61b has the same arrangement with that of the first trans-conductance amplifier 61a except for the resistance of the emitter coupling resistor, R3a and R3b; and the base of the source transistors, Q3b and Q4b, receive the reference Vb through the other switch 64b. The function of the common emitter resistor, R3a and R3b, will be described below in detail.

Two switches, 64a and 64b, operate complementarily, that is, when the signal V4 provided from the comparator 9 is set to the logical level “1” that means the optical input is in the LOS state, one of the switches, 64a and 64b, provides the reference Vb to the base of the source transistors, while, the other switch grounds the base of the other source transistors.

Assuming that the first trans-conductance amplifier 61a has the same arrangement with those of the second trans-conductance amplifier 61b, that is, the size of the differential transistors, Q1a and Q2a, have the same size with the other differential transistors, Q1b and Q2b; the source transistors, Q3a and Q4a, have the same size with the other source transistors, Q3b and Q4b; and the emitter resistors, R4a and R5a, have the same resistance with the emitter resistors, R4b and R5b; then, the differential gain of the trans-conductance amplifier, 61a and 62a, are given by:

A_{V}^{(61a)}=2×R1/{2×V_{T}/I₀+R3a}, and

A_{V}^{(61b)}=2×R1/{2×V_{T}/I₀+R3b},

where V_{T} and I₀ are the thermal voltage defined by kT/q (k: Boltzmann constant, T: absolute temperature, q: electric charge) and the current flowing from the emitter of the differential transistor to the corresponding source transistor. Here, the thermal voltage V_{T} becomes about 25 mV at room temperature. Because the first and second trans-conductance amplifiers, 61a and 61b, are substantially the differential circuit, two load resistors, R1 and R2, have the same resistance and two emitter resistors, R4a and R5a, have the same resistance. Moreover, according to the assumption above where two trans-conductance amplifiers, 61a and 62a, have the same configuration, four emitter resistors, R4a to R5b, have the same resistance.

In two equations above, only the resistance of the emitter coupling resistor, R3a and R3b, is different. Therefore, the voltage gain of the trans-conductance amplifier, 61a and 61b, may be adjusted only by setting the resistance of the emitter coupling resistor, R3a and R3b. On the other hand, the amplitude of the signal output from the terminals, OUTP and OUTN, is determined by the product of the resistance of the load resistor, R1 and R2, and the current flowing therein. As described above, the current flowing four paths from the emitter of the differential transistors to the source transistors is the same magnitude of I₀. Accordingly, the output amplitude of the amplifier, 6a or 6b, becomes equal to 2×I₀×(R1 or R2) in spite of different voltage gains. Thus, the hysteresis controller 6 according to the present embodiment may switch two amplifiers, 6a and 6b, with different voltage gain responding to the LOS status without increasing the power consumption, which enables to set an enough hysteresis width.

Next will describe the operation of the level detector 1 as referring to FIGS. 3A to 3C. FIGS. 3A and 3B show an example of the time behavior of the signal V1 input to the hysteresis controller 6 and a response of the LOS alarm V4 output from the comparator 9, respectively. In a period S1 until an instant T1, the signal V1 monotonically decreases and becomes less than the LOS de-asserting level k2, but still exceeds the. LOS asserting level k1. The output V4 keeps the status “0” that corresponds to the signal detect (SD) and the peak hold 7a receives the output of the first amplifier 6a.

At an instant T1, the signal V1 becomes equal to the LOS asserting level k1 and the output V4 turns to the logical level “1” corresponding to the LOS status. Then the switch 6c switches the input provided to the peak hold 7a from the output of the first amplifier 6a to the second amplifier 6b. In a period S3 from an instant T1 to another instant T2, the signal V1 further decreases, during which the output V4 of the comparator 9 remains the level “1”. In a period S4 from an instant T2 to another instant T3, the signal V1 increases but remains a status less than the LOS de-asserting level k2, which means that the output V4 is still kept in the level “1”. During the period of S3 and S4, the peak hold 7a receives the output of the second amplifier 6b. At an instant T3, the signal V1 becomes equal to the LOS de-asserting level k12, then the output V4 of the comparator turns to the level “0”, which changes the input of the peak hold 7a from the output of the second amplifier 6b to that of the first amplifier 6a.

FIG. 3C explains the time behaviors of the signal V1 input to the hysteresis controller 6 and the output V2 thereof provided to the peak hold 7a. During the period S1, the output V2 decreases on the transition curve G1 of the first amplifier 6a until the output V2 becomes equal to a level denoted as V3 output from the second peak hold 7b, in which the output V4 of the comparator 9 shows the SD state “0”.

When the signal V1 becomes equal to the LOS asserting level k1, the switch 6c switches the input of the peak hold 7a from the output of the first amplifier 6a to that of the second amplifier 6b responding the output V4 from the level “0” to the other level “1”, then the output V2 of the peak hold 7a jumps to the point P2 at step S2. After step S2, the output V2 further decreases on the transition curve G2 of the second amplifier at step S3 to reach the point P3. At step S4, the output V2 monotonically increases on the transition curve of the second amplifier 6b and until it reaches the point P4. The output V4 of the comparator 9 is kept in the level “1” during the steps of S3 and S4. When the output V1 reaches the LOS de-asserting level k2 at the point P4, the switch 6c switches the input of the peak hold 7a from the output of the second amplifier 6b to that of the first amplifier 6a, then the output V2 of the peak hold 7a jumps from the point P4 on the transition curve G2 of the second amplifier 6b to the point P5 on the curve G1 of the first amplifier 6a. The slope of the transition curves, G1 and G2, corresponds to the voltage gain of respective amplifiers, that is, the voltage gain of the first amplifier 6a is greater than that of the second amplifier 6b.

Thus, the level detector 1 according to the present embodiment may show the hysteresis characteristic by switching two amplifiers, 6a and 6b, with respective different voltage gain different from each other depending of the LOS status. Because two amplifiers, 6a and 6b, have substantially same circuit arrangement whose power consumption is also the same; accordingly, the level detector 1 of the embodiment may realize an enough hysteresis characteristic in detecting the LOS status without increasing or changing the power consumption.

The difference in the voltage gain between two amplifiers, 6a and 6b, may be simply performed by setting the resistance of the emitter coupling resistors, 3a and 3b. Further, the dynamic range where the voltage gain shows a linear characteristic is also simply determined by the resistance of the emitter coupling resistor, 3a and 3b. Thus, in the level detector 1 of the embodiment, a preferable performance with an enough hysteresis range may be compatible with the dynamic range of the voltage gain of the amplifier.

Conventionally, a differential amplifier may show a wide dynamic range in the voltage gain thereof by increasing resistance of the load resistor, R1 and R2, or by increasing the current I₀ flowing therein. However, the former technique to increase the resistance is hard to follow a high-speed signal over 10 Gb/s, while, the later technique incurs the increase in the power consumption. The present level detector 1 may show the wide hysteresis characteristic only by adjusting the resistance of one resistor.

While there has been illustrated and described what are presently considered to be example embodiments of the present invention, it will be understood by those skilled in the art that various other modifications may be made, and equivalents may be substituted, without departing from the true scope of the invention. Additionally, many modifications may be made to adapt a particular situation to the teachings of the present invention without departing from the central inventive concept described herein. Therefore, it is intended that the present invention not be limited to the particular embodiments disclosed, but that the invention include all embodiments falling within the scope of the appended claims.

What is claimed is:

1. A signal level detector, comprising:
first and second amplifiers each receiving an input signal;
a switch configured to select one of outputs of said first and second amplifiers;
a peak hold configured to hold an output of said switch; and
a comparator configured to compare an output of said peak hold with a reference,
wherein said first and second amplifiers have same circuit arrangement but different voltage gain and the switch selects one of said outputs of said first and second amplifiers by responding to an output of said comparator.

2. The signal level detector of claim 1,
wherein said first and second amplifiers are a trans-conductance amplifier including a pair of differential transistors and a pair of source transistors each providing a current to one of said differential transistors,
wherein said differential transistors are electrically connected in an emitter thereof to each other through an emitter coupling resistor,
wherein said emitter coupling resistor of said first amplifier has resistance different from resistance of said emitter coupling resistor of said second amplifier.

3. The signal level detector of claim 2,
wherein said trans-conductance amplifier of said first amplifier and said trans-conductance amplifier of said second amplifier have a same load resistor.

4. The signal level detector of claim 3,
wherein said output of said first amplifier and said output of said second amplifier have a same amplitude determined by resistance of said load resistor and a current provided from said source transistors.

5. The signal level detector of claim 2,
wherein said switch makes said source transistors of said first amplifier active and said source transistors of said second amplifier inactive when said first amplifier is selected, and makes said source transistors of said second amplifier active and said source transistors of said first amplifier inactive when said second amplifier is selected.

6. The signal level detector of claim 1,
wherein said input signal is a differential signal.

7. The signal level detector of claim 1,
further providing another peak hold to hold a peak level of said reference,
wherein said comparator compares said output of said peak hold with an output of said other peak hold.
